(19) United States
(12) Patent Application Publication
(10) Pub. No.: US 2008/0055829 A1
(43) Pub. Date: Mar. 6, 2008

(54) Display Swing Mechanism of Portable Terminal

(75) Inventors: Ho-Seong Ko, Gyeonggi-do (KR); Yoong-Yeul Kim, Incheon (KR); Si-Wan Kim, Gyeonggi-do (KR); Byung-Kyu Son, Seoul (KR)

Correspondence Address: HARNESS, DICKEY, & PIERCE, P.L.C, 7700 BONHOMME, STE 400, ST. LOUIS, MO, 63105, US

(73) Assignee: M2SYS CO., LTD., Gyeonggi-do (KR)

(21) Appl. No.: 11/630,386

(22) PCT Filed: Jun. 24, 2005
(86) PCT No.: PCT/KR05/01981

§ 371 Date: Sep. 12, 2007

(30) Foreign Application Priority Data
Jun. 26, 2004 (KR) 10-2004-0048684
Sep. 20, 2004 (KR) 10-2004-0075011
Oct. 7, 2004 (KR) 10-2004-0079789
Dec. 2, 2004 (KR) 10-2004-0100529
Jun. 8, 2005 (KR) 10-2005-0048790

(51) Int. Cl. H05K 5/02

(52) U.S. Cl. 361/681

(57) ABSTRACT

Disclosed is a display tilting mechanism for a communication terminal, in which a display is rotatably connected to a supporter hingedly pivoting on a main body of the communication terminal. The mechanism includes a fixing unit fixedly installed in the supporter. A rotating unit is connected with the display and rotatably installed relative to the fixing unit. A supporting unit is connected with the fixing unit in such a way that the rotating unit is not released when it rotates on the fixing unit. A retaining unit is provided for holding the rotating unit in place at the initial state and rotated state thereof when rotated on the fixing unit. Thus, when watching a movie or the like, the image can be display in a normal orientation.

### TECHNICAL FIELD

The present invention relates to a display tilting mechanism for a portable communication terminal. More specifically, the invention relates to a display tilting mechanism in a communication terminal, in which the liquid crystal window can be rotated into a landscape form.

### BACKGROUND ART

FIG. 1 shows a common communication terminal such as a cellular phone or the like.

In the communication terminal of FIG. 1, a main body 10 and a cover 20 having a liquid crystal display 22 are turned about a hinge 30 to thereby open and close the communication terminal. The hinge 30 only guides the cover 20 from a closed state to an open state, relatively to the main body 10, and vice versa.

On the other hand, the liquid crystal display 22 functions to display various letter or video information. Recently, due to an increase in memory and an improvement in the communication service, movies can be displayed through the liquid crystal display 22 of a portable communication terminal.

In conventional communication terminals, mostly the liquid crystal display 22 is disposed in a vertical direction, i.e., in a portrait fashion. However, movies are displayed in a horizontal direction, i.e., in a landscape fashion. Thus, in order to enjoy the movie, the longer axis of the liquid crystal is required to place in a horizontal direction.

In a case where a movie is display on the liquid crystal display 22 of the conventional communication terminal, part of the display window is not used so that the displayed image is inevitably reduced.

Furthermore, in a case where a vertically oriented liquid crystal display 22 is used in its entirety to display a movie, the displayed image is extended in a vertical direction and reduced in a horizontal direction, thus displaying an abnormal displayed image.

### DISCLOSURE OF INVENTION

Technical Problem

Accordingly, the present invention has been made in order to solve the above problems in the prior art. It is an object of the invention to provide a display tilting mechanism for a communication terminal, in which the display can be rotated into a landscape form using a cam, thereby enabling to watch a movie or the like in a normal, i.e., landscape mode.

Another object of the invention is to provide a display titling mechanism for a communication terminal, in which the display can be rotated and held in place through a leaf spring without using a cam.

A further object of the invention is to provide a swing-type display tilting mechanism for a communication terminal, in which a single display window can be rotated into a landscape form in a swing-motion, thereby enabling to reduce its production cost and watch a movie or the like in a normal orientation, while having the advantages of a folder-type communication terminal.

Technical Solution

In order to accomplish the above objects, according to one aspect of the invention, there is provided a display tilting mechanism for a communication terminal, in which a display is rotatably connected to a supporter hingedly pivoting on a main body of the communication terminal. The display tilting mechanism comprises: a fixing unit fixedly installed in the supporter; a rotating unit connected with the display and rotatably installed relative to the fixing unit; a supporting unit connected with the fixing unit in such a way that the rotating unit is not released when it rotates on the fixing unit; and a retaining unit for holding the rotating unit in place at the initial state and rotated state thereof when rotated on the fixing unit.

A guide shaft is formed in the center of the fixing unit and a guide hole is formed in the center of the rotating unit, the guide shaft being rotatably inserted in to the guide hole.

The retaining unit includes: a cam provided on the rotating unit, the cam forming a cam-line configuration of a rectangular cross-section relative to the rotational center thereof, a latching groove being formed in both ends of a long axial portion and a short axial portion of the cam; slider blocks installed in parallel above and below the fixing unit so as to enable to inwardly and outwardly slide, a spring being installed between corresponding ends of the slider blocks; and a latching portion provided in a central face of each slider block so as to be selectively latched with the latching groove of the cam.

The slider block is provided with a guider formed at both lateral faces thereof such that the slide block can be slidably moved inwardly and outwardly, and the fixing unit is provided with a guide rail at a corresponding inner lateral face thereof so as to support both lateral faces of the guider.

The latching portion includes: a pair of brackets protruded in parallel from the central face of the slider block, a through-hole being formed in the brackets; and a retaining roller rotatably connected to the brackets using a shaft such that the retaining roller is resiliently latched with the latching groove while rolling along the outer face of the cam.

Each of the slider blocks is provided at its both end portions with a hanger groove having a hook-like shape, to which both ends of the spring can be hung.

The fixing unit is provided at its inner face with a guide rib having a desired radius of curvature for rotatably guiding the outer circumferential surface of the rotating unit when it rotates.

The guide shaft is provided with a through-hole formed at the central area thereof, a signal line leading from the supporter to the display passing through the through-hole.

The rotating unit is provided with a connector to be connected with a display and the supporting unit is provided with a through-hole formed therein such that the connector can pass through the through-hole.

The retaining unit includes: a cam provided in the central face of the rotating unit, the cam having a protrusion formed so as to contact the fixing unit and thus restrict the rotating angle of the rotating unit; a slider block pushing the protrusion formed in the cam such that a desired retaining force can be generated at the initial and rotated states of the rotating unit; and a spring providing a resilience force to the slider block.

The fixing unit is provided with a contact portion formed so as to restrict the rotation of the rotating unit to within 90 degrees.

A guide rib is formed in the slider block and the fixing unit is provided with a guide groove formed so as to guide movement of the guide rib.

According to another aspect of the invention, there is provided a display tilting mechanism for a communication terminal, in which a display is rotatably connected to a supporter hingedly pivoting on a main body of the communication terminal. The display tilting mechanism comprises: a fixing unit fixed to the supporter; a rotating unit rotatably coupled to the fixing unit and simultaneously connected to the display, the rotating unit having at least one depressed portion formed at a position corresponding to a restriction angle against the rotation of the display; a retaining unit having a protrusion engaged with the depressed portion to exert a retaining force on the rotating unit, the retaining unit being prevented from being rotated, by means of the fixing unit; and a resilient member generating a resilient force for pressing the retaining unit towards the rotating unit.

A rotation shaft is formed in the central area of the fixing unit, the rotating unit is provided with a rotation hole formed in the central area thereof such that the rotation shaft can be rotatably inserted into the rotation hole, and a connection member is connected to that portion in the rotation shaft that passes through the rotation hole, thereby preventing release of the rotation shaft.

The rotation shaft is provided with a through-hole formed in the central area thereof such that a signal line leading to the display from the supporter passes through the through-hole.

The depressed portion is formed at a position corresponding to a portrait position and a landscape position respectively of the display.

A latching protrusion is formed in the retaining unit, and the fixing unit is provided with a depressed groove formed so as to be engaged with the latching protrusion.

The resilient member is formed of a donut-shaped leaf spring, which is composed of a valley portion contacting with the fixing unit and a ridge portion contacting with the retaining unit.

The fixing unit is provided with a protrusion formed therein such that the display is rotated within a desired range of angle, and the rotating unit is provided with a latching protrusion formed such that the display can be stopped by means of the protrusion at the initial state and the 90-degree rotated state of the display.

According to another aspect of the invention, there is provided with a swing-type display tilting mechanism comprises: a rotating unit fixedly attached to a second body; a fixing unit fixedly attached to a first body, the fixing unit being connected to the rotating unit such that the second body and the first body are rotated relative to and in contact with each other, a clutch member for generating a desired retaining force by being engaged with a depressed portion formed in the rotating unit, the depressed portion being formed in at least one angular position intended to exert the retaining force against rotation of the second body, the clutch member being prevented from rotating by means of the fixing unit; and a resilient member generating a resilient force for pressing the clutch member towards the rotating unit.

A rotation shaft is formed in the central area of the rotating unit, the fixing unit is provided with a rotation hole formed in the central area thereof such that the rotation shaft can be rotatably inserted into the rotation hole, and a connection member is connected to that portion in the rotation shaft that passes through the rotation hole, thereby preventing release of the rotation shaft.

The rotation shaft is provided with a through-hole formed in the central area thereof such that a signal line leading to the second body from the first body passes through the through-hole.

The fixing unit is provided with an insert hole formed so as to receive the clutch member such that the clutch member can be moved together when the fixing unit rotates and simultaneously the clutch member can be allowed to move towards the resilient member and the rotating unit.

The clutch member is formed of a ball, and the depressed portion is formed of a semi-spherical groove with which part of the ball is engaged.

The depressed portion is formed at a position to be engaged with the clutch member at states respectively where the second body closes the first body and the second body is rotated 90-degree or 180-degree relative to the first body.

The resilient member is formed of a C-shaped spring, inner side of which is contacted with the clutch member to thereby press the clutch member towards the depressed portion.

The fixing unit is provided with a protrusion protruded towards the resilient member, and the opening of the resilient member is latched with the protrusion to thereby rotate along with the fixing unit.

The swing-type display tilting mechanism may further comprise a retaining unit for preventing excessive rotation of the rotating unit in a particular direction.

Alternatively, the swing-type display tilting mechanism may further comprise a retaining unit installed such that the rotating unit can be rotated in both directions relative to the fixing unit and cannot be further rotated from a state rotated with certain predetermined degrees.

The retaining unit includes: a retaining ring rotatably installed between the rotating unit and the fixing unit, the retaining ring being provided with a first latching protrusion formed to the rotating unit side and a second latching protrusion formed to the fixing unit side; a third latching protrusion formed in the rotating unit and contacting the first latching protrusion to be retained; and a rotation-limiting protrusion formed in the fixing unit so as to be placed in both sides respectively of the second latching protrusion and spaced apart from each other by the total length of the first latching protrusion, the second latching protrusion and the third latching protrusion, wherein, when the rotating unit rotates, the rotation-limiting protrusion contacts one of the both end portions of the second latching protrusion along its rotating direction to thereby retain the retaining ring.

According to another aspect of the invention, there is provided a swing-type display tilting mechanism for a communication terminal. The swing-type display tilting mechanism comprise: a fixing unit; a rotating unit rotatably coupled to the fixing unit; an oval cam fixed to the rotating unit; a mobile block installed in the fixing unit so as to move towards and away from the rotational center of the cam; and a resilient member for exerting a resilient force on the mobile block.

Either one of the fixing unit and the rotating unit is provided with a rotation hole formed therein, and a rotation shaft is fixed to the other one thereof so as to be rotatably coupled to the rotation hole.

The rotation shaft has a center hole formed in the center thereof.

The rotating unit is configured to rotate in either direction relative to the fixing unit.

The cam is fixed in a place eccentric from the rotational center of the rotating unit.

The swing-type display tilting mechanism may further comprise a clutch means for holding the rotating unit in place at un-rotated state and at a certain degree-rotated state thereof.

The clutch means is formed of a protrusion formed in the mobile block, a first depressed portion to be engaged with the protrusion is formed in the outermost portion protruding from the rotational center of the cam, and a second depressed portion to be engaged with the protrusion is formed in a symmetrical place with the first depressed portion about the rotational center.

A third depressed portion to be engaged with the protrusion is formed between the first depressed portion and the second depressed portion.

The mobile block is constricted to push the cam to rotate the rotating unit, when the protrusion is released from the first depressed portion.

The mobile block is provided with a guide rail formed in the moving direction of the mobile block, and the fixing unit is provided with a guide groove with which the guide rail is slidably connected.

The resilient member is formed of at least one compression spring which is supported by the fixing unit and pushes the mobile block towards the cam.

The swing-type display tilting mechanism may further comprise a cover connected to the fixing unit from the outside of the rotating unit, thereby preventing the rotating unit from being released from the fixing unit, and the cover is provided with an opening hole formed so as to expose part of the rotating unit.

The swing-type display tilting mechanism may further comprise a retaining unit for holding the rotating unit in plate at a certain degree-rotated state relative to the fixing unit.

The retaining unit includes a latching protrusion fixed to either one of the fixing unit and the rotating unit, and a latching plate fixed to the other one thereof for retaining the protrusion.

Alternatively, the retaining unit may include a latching protrusion fixed to either one of the fixing unit and the rotating unit, and a latching plate formed in the other one thereof so as to move in the rotation direction of the latching protrusion such that the latching protrusion can be retained at the 180-degree rotated state in either direction.

Either one of the fixing unit and the rotating unit is provided with an arcuate groove formed such that the latching protrusion can be movably inserted thereinto, wherein the arcuate groove has a size to limit the movement of the latching plate such that the latching protrusion is retained in plate by the latching plate at a state 80-degree rotated in either direction.

The latching plate is fixed to a ring, which is rotatably connected to the central shaft of the rotating unit.

### ADVANTAGEOUS EFFECTS

As described above, in the present invention, the display can be rotated into a landscape form at the state where it is turned about a hinge relative to the main body.

Thus, when watching a movie or the like, the image can be display in a normal orientation.

In addition, with a folder-type terminal, the display can be rotated into a landscape form such that an image can be displayed in a landscape mode when watching a movie or the like.

### BRIEF DESCRIPTION OF THE DRAWINGS

Further objects and advantages of the invention can be more fully understood from the following detailed description taken in conjunction with the accompanying drawings in which:

FIG. 1 is a perspective view showing a conventional communication terminal;

FIGS. 2 and 3 are a frontal view and a rear view illustrating a display tilting mechanism of a communication terminal according to an embodiment of the invention;

FIGS. 4 to 6 conceptually illustrate the operation of the display tilting mechanism of the invention;

FIG. 7 is an exploded perspective view showing a communication terminal having a display tilting mechanism according to another embodiment of the invention;

FIGS. 8 and 9 are exploded perspective views of the display tilting mechanism of FIG. 7;

FIG. 10 is a cross-sectional view of the display tilting mechanism of FIG. 8;

FIGS. 11 to 13 are cross-sectional views showing the operational state of the display tilting mechanism of FIG. 8;

FIG. 14 is a perspective view of the communication terminal of FIG. 7 combined with the display tilting mechanism;

FIGS. 15 and 16 are perspective views of the communication terminal of FIG. 9 when in use;

FIG. 17 is an exploded perspective view showing a communication terminal having a display tilting mechanism according to yet another embodiment of the invention;

FIG. 18 is an exploded perspective view of the display tilting mechanism of FIG. 17;

FIG. 19 is a cross-sectional view of the display tilting mechanism of FIG. 18;

FIGS. 20 to 22 are cross-sectional views showing the operational state of the display tilting mechanism of FIG. 18;

FIG. 23 is a perspective view of the communication terminal of FIG. 17 combined with the display tilting mechanism;

FIGS. 24 and 25 are perspective views of the communication terminal of FIG. 23 when in use;

FIG. 26 is an exploded perspective view showing a communication terminal having a display tilting mechanism according to an embodiment of the invention;

FIG. 27 is an exploded perspective view showing the display tilting mechanism of FIG. 26;

FIG. 28 is another exploded perspective view seen from a different angle;

FIGS. 29 and 30 are cross-sectional views showing an assembled state of the display tilting mechanism of FIG. 27;

FIGS. 31 and 32 are cross-sectional views of the display tilting mechanism of FIG. 28 when in use;

FIG. 33 is a perspective view showing an assembled state of the communication terminal of FIG. 27;

FIGS. 34 and 35 are perspective views showing the communication terminal of FIG. 33 when in use;

FIG. 36 is an exploded perspective view of a swing-type display tilting mechanism according to an embodiment of the invention;

FIG. 37 is another exploded perspective view seen from a different angle;

FIG. 38 is a transversal cross-section showing an assembled state of the display tilting mechanism of FIG. 36;

FIG. 39 is a transversal cross-section showing the display tilting mechanism of FIG. 38 where the rotating unit starts to rotate;

FIG. 40 is a transversal cross-section showing the display tilting mechanism where the rotating unit is 180-opened;

FIG. 41 is a transversal cross-section showing the display tilting mechanism where the rotating unit is 90-opened;

FIG. 42 is an exploded perspective view of the display tilting mechanism assembled to a portable communication terminal;

FIG. 43 is a vertical cross-sectional view of the display tilting mechanism assembled to a portable communication terminal;

FIG. 44 is a perspective view showing an assembled state of the portable communication terminal of FIG. 41;

FIG. 45 is a perspective view of the portable communication terminal where the display starts to open;

FIG. 46 is a perspective view of the portable communication terminal of FIG. 44 where the display is 180-opened; and

FIG. 47 is a perspective view of the portable communication terminal of FIG. 45 where the display is 90-opened.

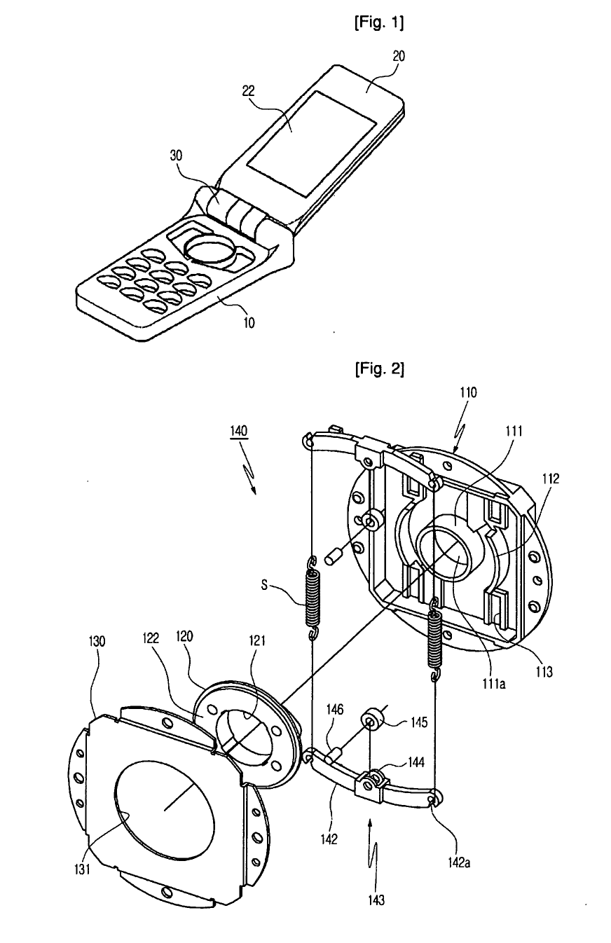

### BEST MODE FOR CARRYING OUT THE INVENTION

The preferred embodiments of the present invention will be hereafter described in detail with reference to the accompanying drawings.

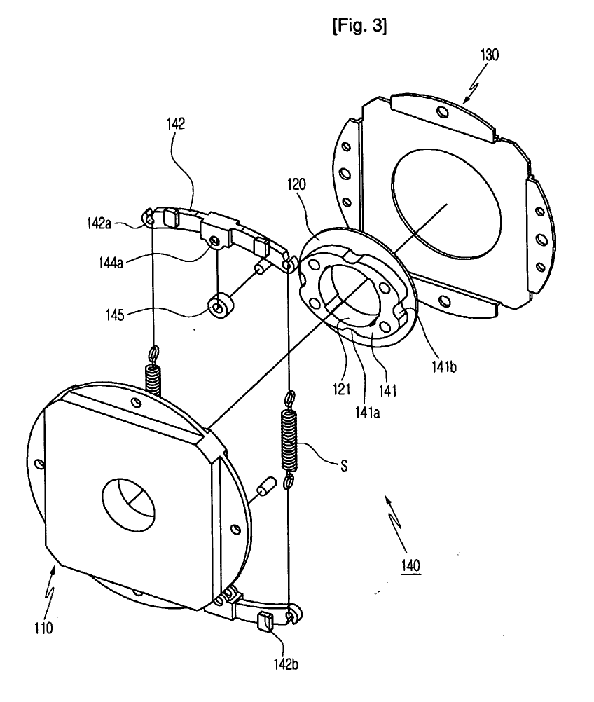

FIGS. 2 to 6 illustrate a display tilting mechanism according to a first embodiment of the invention.

As illustrated in FIGS. 2 to 6, the display tilting mechanism of the invention, in general, includes a fixing unit 110, a rotating unit 120, a supporting unit 130, and a retaining unit 140.

The fixing unit 110 is fixedly installed in a supporter 2 hingedly rotating on a main body 1. The fixing unit 110 is provided with a guide shaft 111 having a through-hole 111a formed in the center thereof.

Here, a signal line leading to a display (not shown) from the supporter passes through the through-hole 111a provided in the guide shaft 111.

The rotating unit 120 is to be connected to the display and is provided with a guide hole 121 formed so as to be able to rotate along the outer circumferential surface of the guide shaft 111 inside the fixing unit 110.

The supporting unit 130 is connected to the fixing unit 110 such that the rotating unit 120 can be rotated while not being released from the fixing unit 110.

On the other hand, the fixing unit 110 is provided with a guide rib 112 having a desired radius of curvature formed outwards of the guide shaft 111. The guide rib 112 guides the outer peripheral face of the rotating unit 120 to thereby stabilize the rotation of the rotating unit 120 when it is rotated.

In addition, the rotating unit 120 is provided with a connector 122 formed so as to be connected with a display and the supporting unit 130 is provided with a through-hole 131 formed for the connector 122 to pass through.

The retaining unit 140 is provided for holding the rotating unit 120 in place at the initial state and rotated state thereof.

The retaining unit 140 is generally comprised of a cam 141, a slider block 142, and a latching portion 143.

The cam 141 is provided on the rotating unit 120 and forms a cam-line configuration having a rectangular cross-section. The cam-line configuration is composed of a short axial portion and a long axial portion, relative to the central axis of the rotating unit 120. In particular, latching grooves 141a and 141b having a desired depth respectively are formed in both sides of the respective long and short axial portions.

The slider blocks 142 are installed above and below the fixing unit 110 in parallel to each other. The slider block 142 is installed so as to enable to inwardly and outwardly slide towards the center of the fixing unit 110. In particular, a spring S is installed in both ends of the respective slider blocks 142 in such a way to connect the corresponding ends in the slider blocks.

Here, preferably, the slider block 142 is provided with a hanger groove 142a having the shape of a hook at the both ends of the slider block 142, to which both ends of the spring S can be firmly connected.

Furthermore, in order for the slider block 142 to smoothly perform a sliding motion on the fixing unit 110, preferably the slider block 142 is provided with a guider 142b formed at both lateral faces thereof. In addition, the fixing unit 110 is provided with a guide rail 113 for guiding both outer faces of the guider 142b.

The latching portion 143 is provided at the center of each slider block 142. Practically, the latching portion 143 is resiliently latched with the latching grooves 141a and 141b of the cam 141 by means of the resilience of the spring S, thus resiliently supporting the position of the rotating unit 120.

The above latching portion 143 may be integrally formed in the central face of the slider block 142. Alternatively, it is preferable that a pair of brackets 144 having a th rough-hole 144a formed thereon is installed so as to be protruded from the central face of the slider block 142 and a retaining roller 145 is rotatably connected to the bracket 144 using a shaft 146. Thus, the retaining roller 145 is resiliently latched with the latching groove 142a, thus enabling more smooth operation thereof.

The operation of the display tilting mechanism of a communication terminal having the above-described construction according to the invention will be explained below.

First, in FIG. 4, the display is vertically positioned in a portrait form, and the retaining roller 145 constituting the latching portion 143 remains latched with the latching groove 141a, which is positioned in the short axial portion side of the cam 141.

Of course, the retaining roller 145 is resiliently latched with the latching groove 141a by means of the spring S connected between the slider blocks 142.

At this state, in order to use the entire display window to watch a movie or the like, the display can be rotated in a horizontal direction, i.e., in a landscape fashion. Then, the rotating unit 120, to which the display is connected, is rotated clockwise or counterclockwise and simultaneously the cam 141 integrally formed in the inner face of the rotating unit 120 is rotated together.

In this way, when the cam 141 is rotated by means of the rotating unit 120, the latching state between the latching groove 141 in the short axial side and the retaining roller 145 constituting the retaining unit 140 is released while overcoming the resiliency of the spring S. Due to the outer face of the cam 141, as the retaining roller 145 moves towards the long axial side, the retaining roller 145 is biased outwardly.

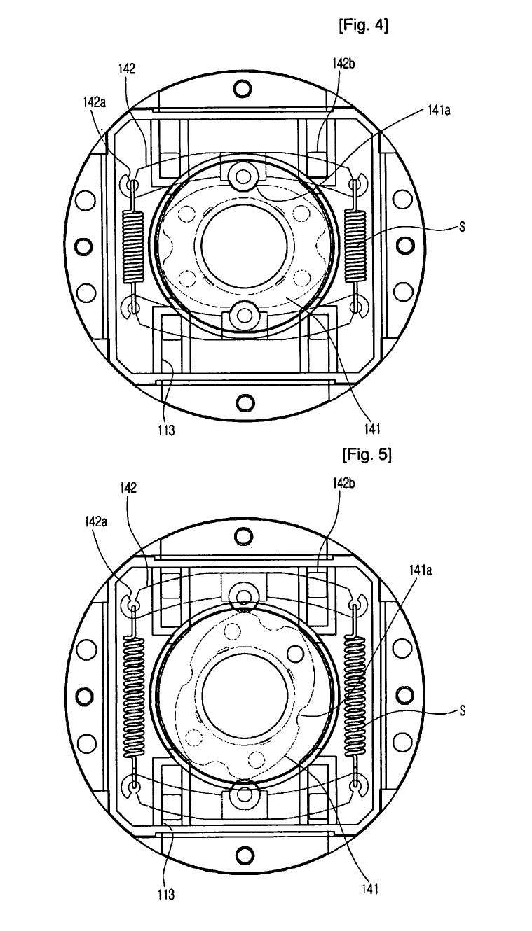

Thus, as illustrated in FIG. 5, each slider block 142 having the retaining roller 145 at its center slidably moves outwards of the fixing unit 110.

At this time, the slider block 142 moves smoothly without wobbling, due to the guider 142b provided in the inner side of the slider block 142 and the guide rail 113 provided on the corresponding fixing unit 110.

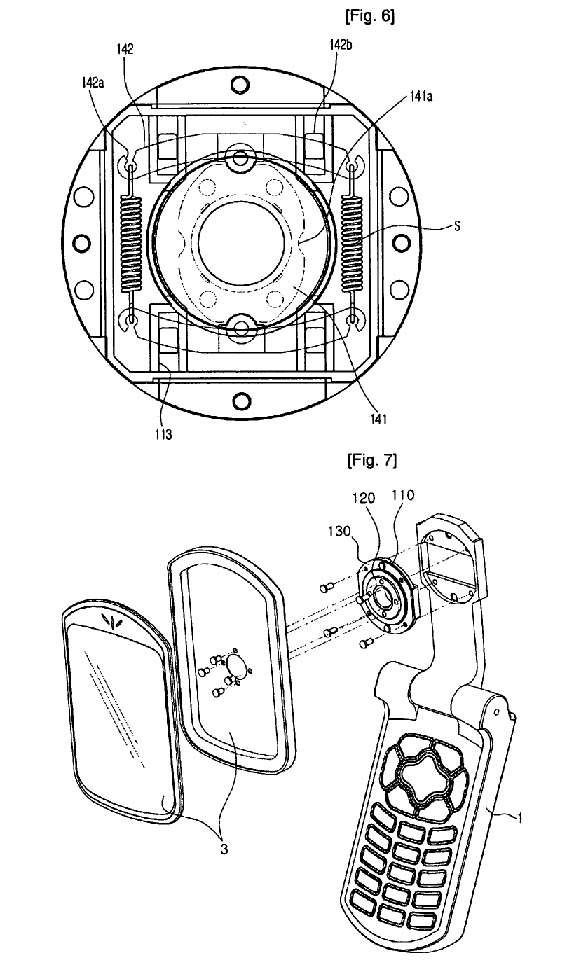

In addition, as shown in FIG. 6, when the retaining roller 145 is placed in the long axial side of the cam 141, it is slidably latched with the latching groove 141b and remains in the latched state by means of the resilience of the spring S.

Therefore, the display connected to the rotating unit 120 firmly remains in the horizontal state unless the rotating unit 120 is forcibly rotated to overcome the spring force.

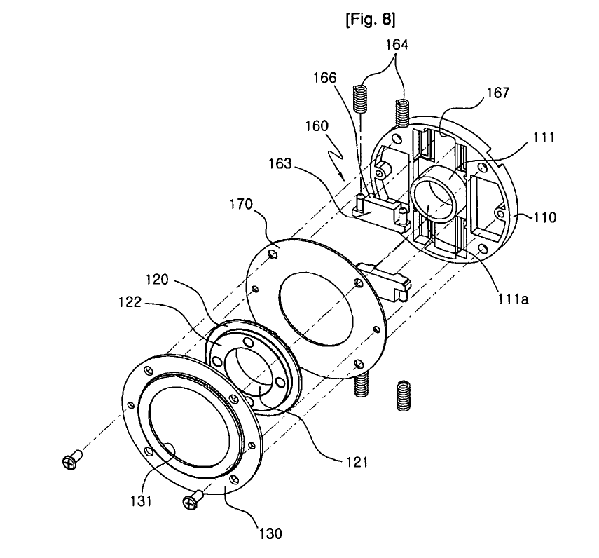

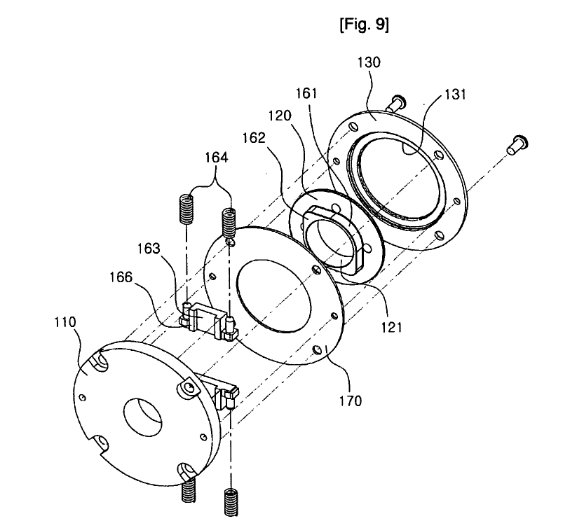

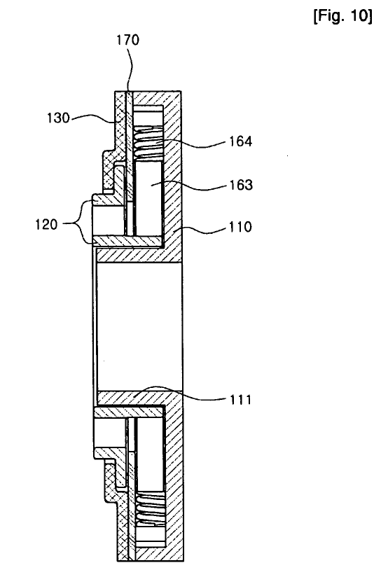

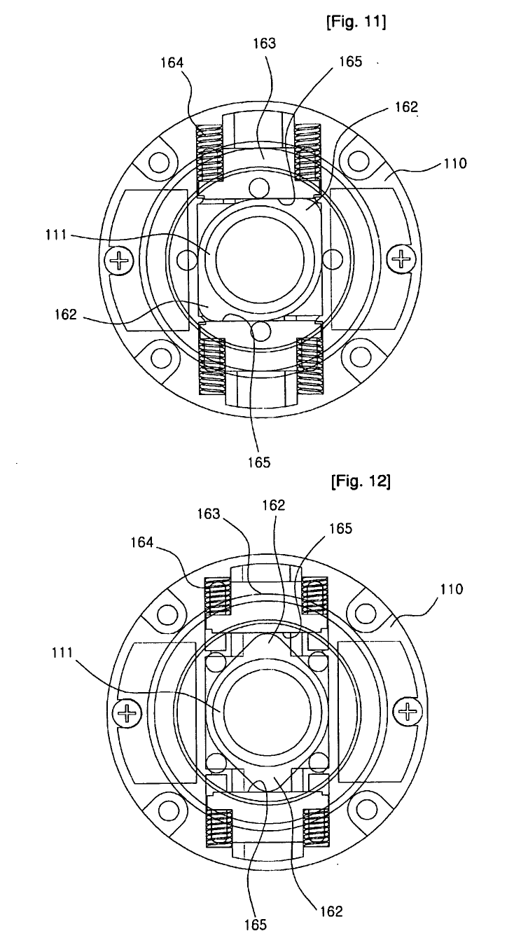

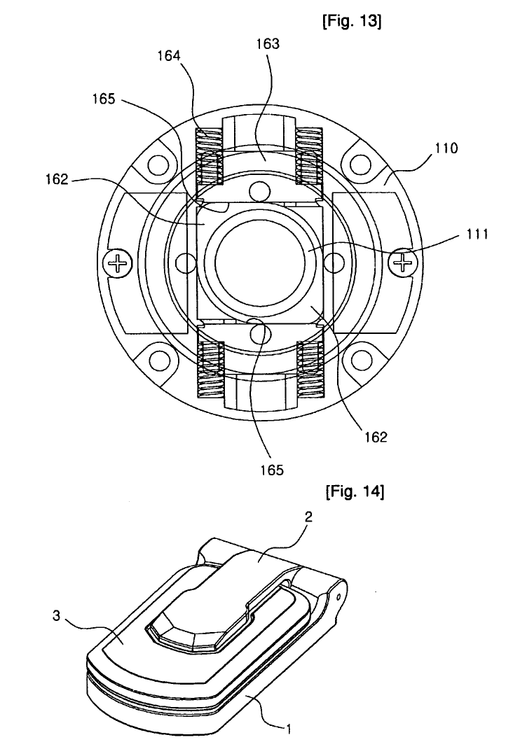

On the other hand, FIGS. 7 to 16 illustrate a display tilting mechanism in a communication terminal according to another embodiment of the invention where the retaining unit is modified in a different mode.

Hereinafter, this embodiment will be explained, referring to FIGS. 7 to 16 and also FIGS. 2 to 6, and like components are denoted by like reference numerals.

A fixing unit 110 is fixedly installed in a supporter 2, which hingedly rotates relative to a main body 1. Formed in the central face is a guide shaft 111 having a through-hole 111a.

Here, a signal line leading to the display 3 from the supporter 2 passes through the through-hole 11 a provided in the guide shaft 111.

A rotating unit 120 is combined with the display. The rotating unit 120 is provided with a guide hole 121 formed so as to rotate along the outer circumferential surface of the guide shaft 111 within the fixing unit 110.

A supporting unit 130 is connected to the fixing unit 110 such that the rotating unit 120 can be rotated without being released from the fixing unit 110.

On the other hand, the fixing unit 110 is provided with a guide rib 112 having a desired radius of curvature formed outwards of the guide shaft 111. The guide rib 112 guides the outer peripheral face of the rotating unit 120 to thereby stabilize the rotation of the rotating unit 120 when it is rotated.

In addition, the rotating unit 120 is provided with a connector 122 formed so as to be connected with a display and the supporting unit 130 is provided with a through-hole 131 formed for the connector 122 to pass through.

On the other hand, dissimilar to the first embodiment, in the structure of the retaining unit 160, the rotating unit 120 is provided at its central face with a cam 161 for contacting with the fusing unit 110 to thereby restricting the rotation angle of the rotating unit 120. A protrusion 162 is formed in the cam 161.

Here, the fixing unit 110 is provided with a contact portion 165, to which the protrusion 162 is contacted to thereby restrict the rotation of the cam 161 within 90 degrees.

A slider block 163 is provided to push the protrusion 162 formed in the cam 161 and thus provides a retaining force to the rotating unit 120 in the initial and rotated state thereof.

In addition, a spring 164 is further provided therebetween to provide a resilient force to the slider block 163.

Furthermore, the slider block 163 is provided with a guide rib 166 for smooth operation of the slider block 163, and the fixing unit 110 is provided with a guide groove 167 for guiding the movement of the guide rib 166.

Here, reference numeral 170 denotes a cover.

In the display tilting mechanism having the above-described construction, the display 3 of the communication terminal is coupled to the supporter 110 in a portrait form and covers the main body 1.

At this state, the slider block 163 pushes the protrusion 162 of the cam 162 towards the contact portion 165 with a desired resilient force, so that the rotating unit 120 and the display 3 remain in a closed state.

At this time, if a user lifts the display 3 up, the supporter 2 turns around a hinge 4 to open the display 3.

Then, if the display 3 is rotated in one direction, the rotating unit 120 is rotated around the guide shaft 111 by 90 degrees, together with the display 3. During this process, the slider block 163 overcomes the resilience of the spring 164 and moves towards the opposite contact portion 165. Thereafter, the slider block 163 pushes the protrusion 162 towards the opposite contact portion 165 with a desired resilient force so that the rotating unit 120 and the display 3 remains in the opened state.

Since the protrusion 162 moves only between both contact portions 165, the display 3 and the rotating unit 120 rotate within 90 degrees.

On the other hand, if the display rotates 90 degrees, the liquid crystal window of the display 3 takes a landscape form In this state, the liquid crystal window can display a move in a normal size.

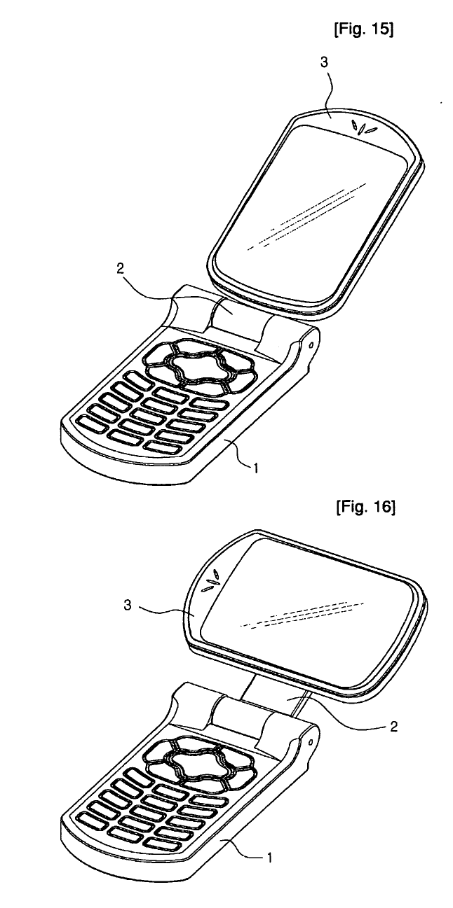

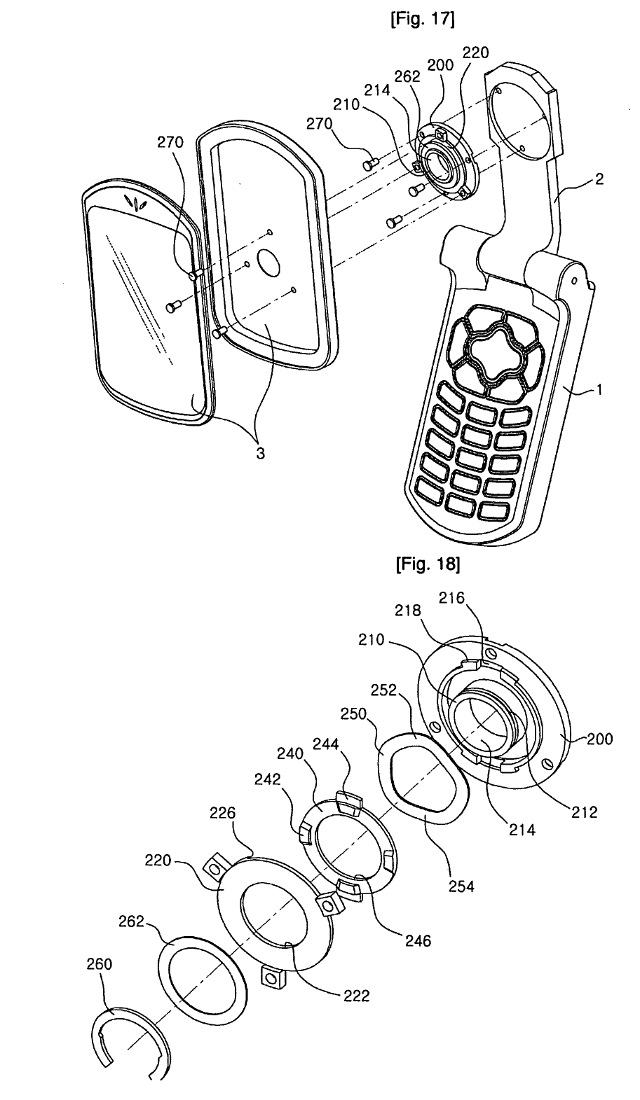

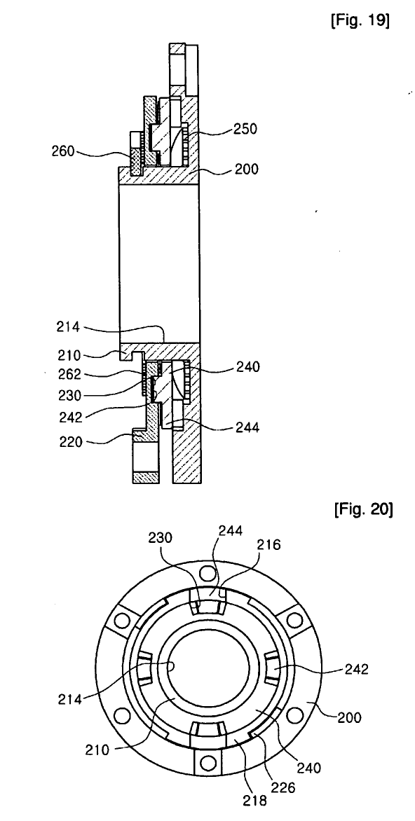

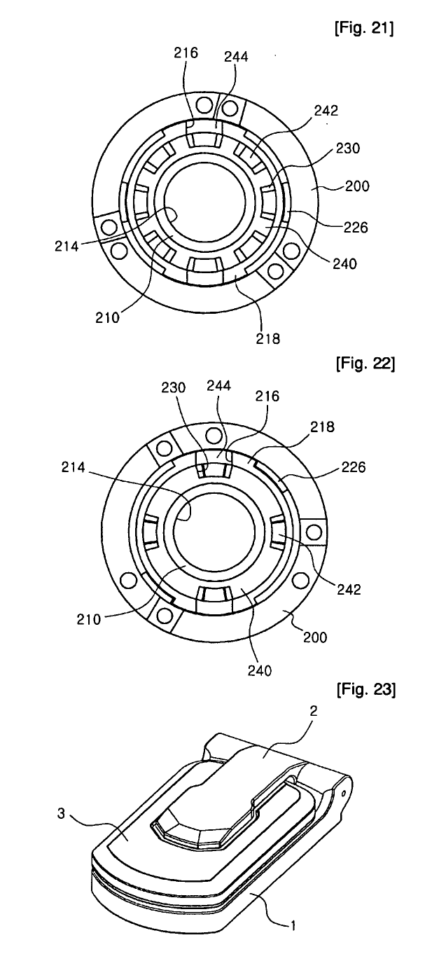

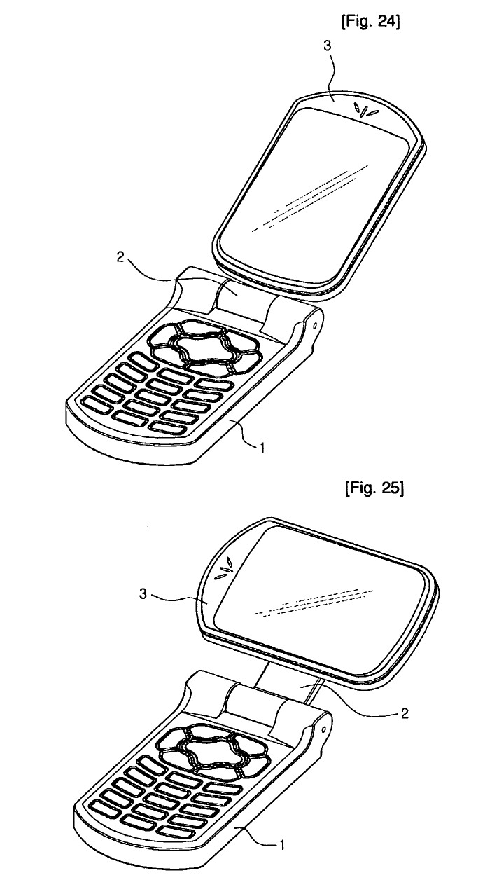

FIGS. 17 to 25 illustrate a display tilting mechanism according to another embodiment of the invention.

As illustrated in the figures, in this embodiment, a supporter 2 is hinge-coupled to a main body 1, and the display tilting mechanism rotatably combines the display 3 with the supporter 2.

The display tilting mechanism of this embodiment includes a fixing unit 200, a rotating unit 220, a retaining unit 240, and a resilient member 250. The rotating unit 220 is rotatably coupled to the fixing unit 200 and also to a display 3. The rotating unit 220 is provided with at least one depressed portion at a position, which corresponds to a restriction angle against the rotation of the display 3. The retaining unit 240 has a protrusion 242 combined with the depressed portion 230 to exert a retaining force to the rotating unit 220. By means of the fixing unit 200, the retaining unit 240 is prevented from being rotated. The resilient member 250 generates-a resilient force for pressing the retaining unit 240 towards the rotating unit 220.

The fixing unit 200 is coupled to the supporter 2 using a screw 270, and the rotating unit 220 is coupled to the display 3 using a screw 270.

The fixing unit 200 is provided with a rotation shaft 210 formed in its central area, and the rotating unit 220 is provided with a rotation hole 222 formed in the central area thereof for the rotation shaft 210 to be rotatably inserted thereinto. A connection member is connected to that portion in the rotation shaft 210 that passes the rotation hole 222, thus preventing the rotation shaft 210 from being released.

The above connection member is composed of a washer 262 and a sealing 260, which are coupled to an annular groove 212 formed in the rotation shaft 210.

In addition, formed in the central area of the rotation shaft 210 is a through-hole 214, through which a signal line leading to the display 3 from the supporter 2 passes.

On the other hand, the depressed portion 230 of the rotating unit 220 is formed at a position, which corresponds to a portrait position and a landscape position respectively of the display 3. That is, the depressed portions 230 are formed such that the liquid crystal display window can be retained at the vertical position thereof and a 90-degree rotated state in one or both directions.

In addition, the retaining unit 240 has a latching protrusion 244, and the fixing unit 200 has a depressed groove 216 with which the latching protrusion 244 is engaged, thus preventing the retaining unit 240 from rotating together with the rotating unit 220. Formed in the central area of the retaining unit 240 is a central hole 246, through which the rotation shaft 210 passes.

Furthermore, in order for the display 3 to be rotated within a desired range of angle, the fixing unit 200 is provided with a protrusion 218 formed therein. The rotating unit 220 is provided with a latching protrusion 226 formed such that the display 3 can be stopped by means of the protrusion 218 at the initial state and the 90-degree rotated state of the display.

On the other hand, the resilient member 250 is formed of a donut-shaped leaf spring, which is composed of a valley portion 252 contacting with the fixing unit 200 and a ridge portion 254 contacting with the retaining unit 240.

In the communication terminal having the above-described construction, when the liquid crystal window in the display 3a is rotated, a control unit rotates the image (displayed in the liquid crystal window) in the opposite direction by the same angle as the rotation of the display. Thus, the image can be properly displayed. For this purpose, the control unit has a separate sensor (not shown) for measuring the rotation angle of the display 3.

Hereinafter, the operation of the above-constructed display tilting mechanism of a communication terminal will be explained.

At the initial state, the display 3 of the communication terminal is coupled to the supporter 2 in a portrait fashion and covers the main body 1.

At this state, the protrusion 242 of the retaining unit 240 is engaged with the depressed portion 230 of the rotating unit 220 and a desired retaining force for holding the rotating unit 220 in place is generated by means of the resilience of the resilient member 250. Thus, the rotating unit 220 and the display 3 connected thereto remain in the portrait position.

On the other hand, if a user lifts the display 3 up, the supporter 2, by which the display 3 is supported, turns around a hinge 4 to open the liquid crystal window of the display 3.

At this state, the inherent functions of the communication terminal can be performed.

When an image such as a movie needs to be displayed through the liquid crystal window, the display 3 is tilted in one direction.

Accordingly, the rotating unit 220 starts to rotate around the rotation shaft 210, along with the display 3.

During this process, the resilient member 250 continues to exert a resilient force to the retaining unit 240, which thereby closely contacts the rotating unit 220.

On the other hand, when the display 3 rotates 90-degrees, the liquid crystal window of the display 3 takes a landscape form. At the same time, the control unit detects the rotation of the display 3 through a sensor and outputs the image in a landscape mode. Thus, a user can watch the movie or the like properly through the landscaped display window.

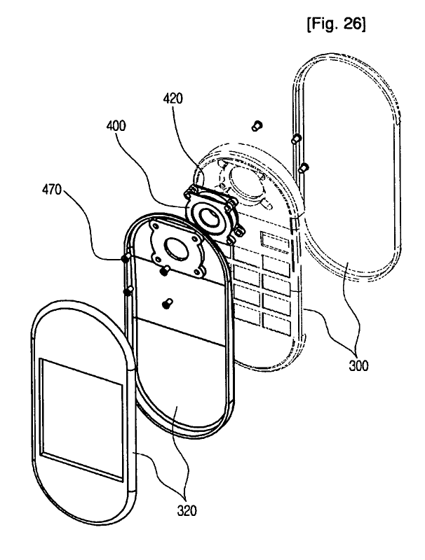

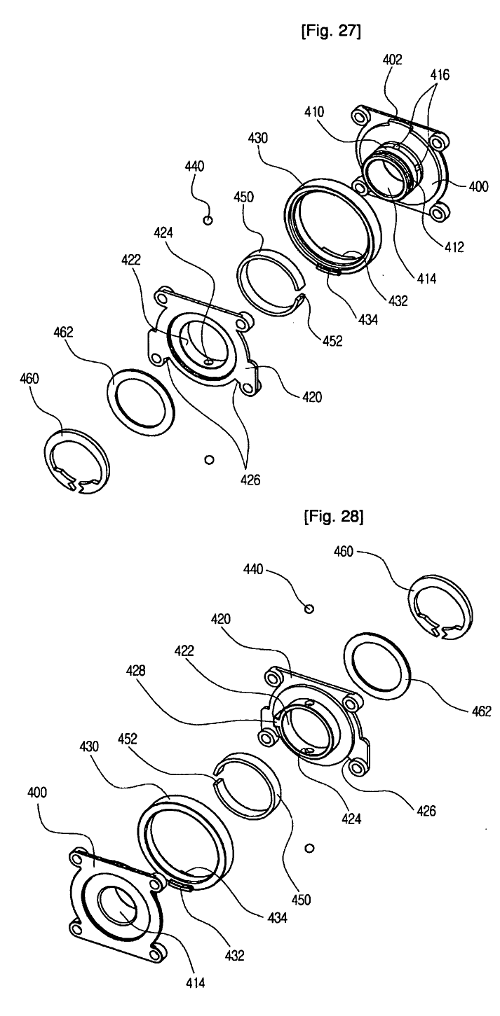

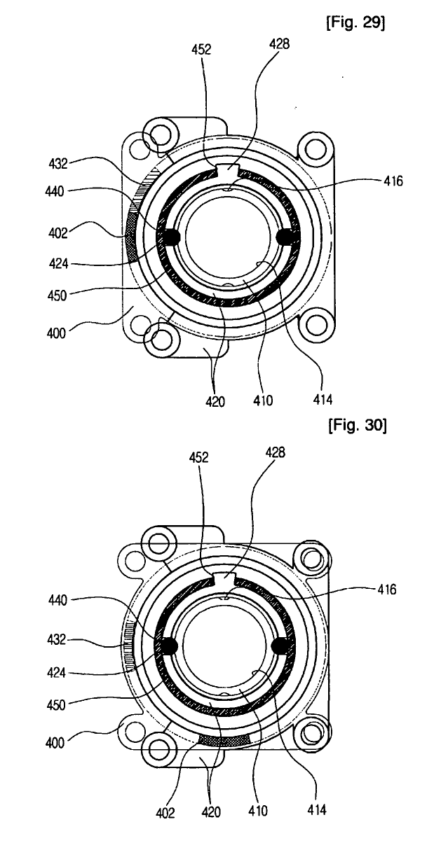

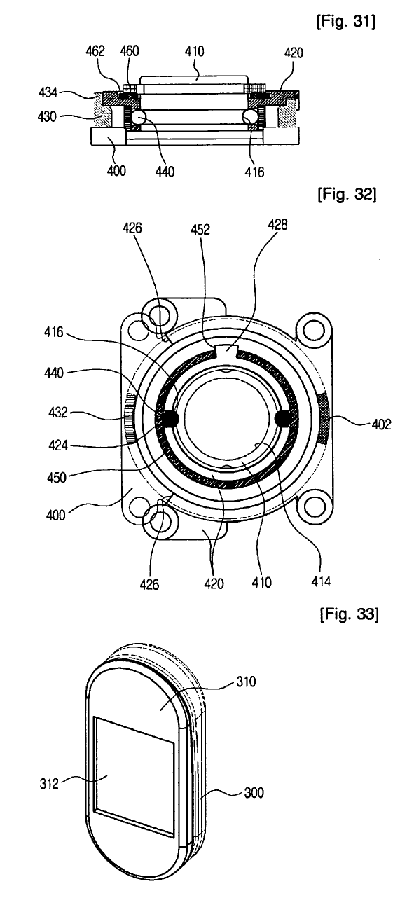

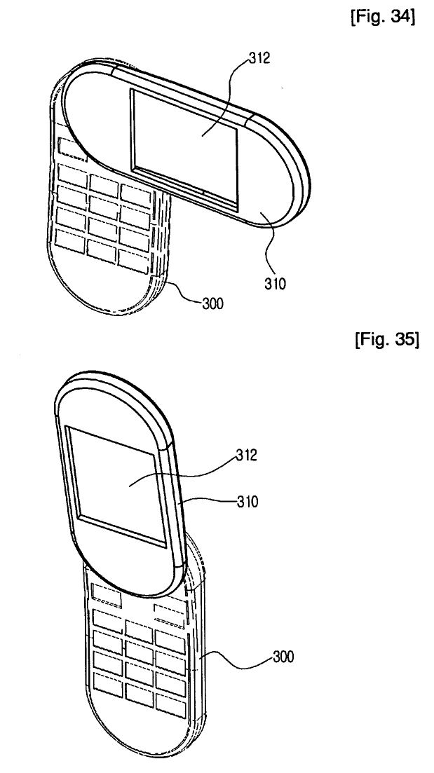

FIGS. 26 to 35 illustrate a swing-type display tilting mechanism of a communication terminal according to an embodiment of the invention.

As illustrated in FIGS. 26 to 35, the display tilting mechanism of this embodiment includes a rotating unit 400 fixed to a second body 320 and a fixing unit 420 fixed to a first body 300. The fixing unit 420 is coupled to a rotating unit 400 such that the first body 310 and the second body 300 can be tilted relative to each other.

In addition, the display tilting mechanism includes a clutch member for generating a desired retaining force and a resilient member for pressing the clutch member towards the rotating unit 400. The clutch member is prevented from rotating by means of the fixing unit 420, and engaged with a depressed portion formed in the rotating unit 400 to thereby generate the retaining force. The depressed portion is formed in at least one angular position, which is intended to exert a retaining force against rotation of the second body 310.

A rotation shaft 410 is formed in the central area of the rotating unit 400, and the fixing unit 420 is provided with a rotation hole 422 formed in its central area such that the rotation shaft 410 can be rotatably inserted thereinto.

In addition, a connection member is connected to that portion in the rotation shaft 410 that passes through the rotation hole 422, thus preventing release of the rotation shaft 410.

The above connection member is composed of a washer 462 and a sealing 460, which are coupled to an annular groove 412 formed in the rotation shaft 410.

Formed in the central area of the rotation shaft 410 is a through-hole 414, through which a signal line leading to the second body 310 from the first body 300 passes.

The fixing unit 420 is provided with an insert hole 424 formed so as to receive the clutch member such that the clutch member can be moved together when the fixing unit 420 rotates and also the clutch member can be allowed to move towards the resilient member and the rotating unit 400.

The clutch member is formed of a ball 440, and the depressed portion is formed of a semi-spherical groove 416, with which part of the ball 440 is engaged.

The semi-spherical groove 416 is formed in a position where the ball 440 is engaged when the second body 310 closes the first body 300 and the second body 310 is rotated 90-degrees or 180 degrees relative to the first body 300 respectively.

The resilient member is formed of a C-shaped spring 450, inner side of which is contacted with the ball 440 to thereby press the ball towards the semi-spherical groove 416.

The fixing unit 420 is provided with a protrusion 428 protruded towards the C-shaped spring 450, and the opening 452 of the C-shaped spring 450 is latched with the protrusion 428 to thereby rotate along with the fixing unit 420.

The rotating unit 400 and the fixing unit 420 are fixedly attached to the first body 300 and the second body 110 respectively, using a screw 470.

On the other hand, the rotating unit 400 is installed so as to rotate in both directions relative to the fixing unit 420. A retaining unit is installed such that the rotating unit 400 cannot be further rotated from a state rotated with a certain degree.

The above retaining unit includes a retaining ring 430 rotatably installed between the rotating unit 400 and the fixing unit 420. The retaining ring is provided with a first latching protrusion 432 formed to the rotating unit side and is provided with a second latching protrusion 434 formed to the fixing unit side 420.

In addition, the rotating unit 400 is provided with a third latching protrusion 402 for contacting the second latching protrusion 434 to thereby perform a retaining function. The fixing unit 420 is provided with a rotation-limiting protrusion 426 formed so as to be placed in both sides of the second latching protrusion 434 respectively, spaced apart therefrom by the total length of the first latching protrusion 432, the second latching protrusion 434 and the third latching protrusion 402. When the rotating unit 400 rotates, the rotation-limiting protrusion 426 contacts one of the both end portions of the second latching protrusion 434 along its rotating direction to thereby retain the retaining ring 430.

As described above, the rotation-limiting protrusion 426 is placed in both sides of the second latching protrusion 434 respectively, spaced apart therefrom by the total length of the first latching protrusion 432, the second latching protrusion 434 and the third latching protrusion 402. Thus, when the fixing unit 420 is rotated to the both directions respectively, in both cases, the fixing unit 420 is accurately rotated 180-degrees and thereafter the second latching protrusion 434 comes to be latched with the third latching protrusion 402.

In the communication terminal having the above construction, when the fixing unit 420 is rotated 90-degree or 180-degree, the control unit functions to rotate the output image in the opposite direction by the same degrees as the rotation angle of the liquid crystal window 312. Thus, the image can be displayed in normal orientation.

For this purpose, the control unit is provided with a separate sensor (not shown) for measuring rotation angle of the fixing unit 420.

Hereafter, the operation of the above-described display tilting mechanism will be explained.

In the usual state, the second body 310 of the communication terminal remains closed with the first body 300.

At this state, the ball 440 is engaged with the semi-spherical groove 416 of the rotating unit 400 by means of the resilient force of the C-shaped spring 450, thus generating a desired retaining force to hold the rotating unit in place. Accordingly, the rotating unit 400 and the second body 310 connected thereto remain stopped.

On the other hand, when a user rotates the second body 310 in a lateral direction, the rotating unit 400 fixed to the second body 310 starts to rotate around the rotation shaft 410.

In the initial rotation of the rotating unit 400, the ball 440 overcomes the force of the C-shaped spring 450 by means of the rotation of the rotating unit 400 and is thus released from the semi-spherical groove 416 of the rotating unit 400 to thereby rotate.

Thereafter, when the second body 310 rotates 90-degree, again the ball 440 is inserted into the semi-spherical groove 416 of the rotating unit 400 and pressed thereinto by means of the C-shaped spring 450 to generate a retaining force. Thus, the second body 310 remains in a 90-degree rotated state by the retaining force.

In addition, when the second body 310 is rotated 90-degree, the liquid crystal window 312 takes a landscape form. The control unit detects the rotation of the rotating unit 400 through the sensor and controls the image output to the liquid crystal window 312 so as to be displayed in a landscape mode. The user can watch a movie and the like in a proper orientation through the tilted liquid crystal window 312.

Subsequently, when the user continues to rotate the second body 310, again the rotating unit 400 fixed to the second body 310 rotates around the rotation shaft 410. At this time, since the ball 440 is fixed by means of the fixing unit 420, the ball 440 overcomes the pressing force of the C-shaped spring 450 and is thus released from the semi-spherical groove 416 and rotates.

Thereafter, when the second body 310 is rotated 180-degree, the ball 440 again is inserted into the semi-spherical groove 416 and pressed by the C-shaped spring 450 to generate a desired retaining force. Thus, the second body 410 can remain in the 180-degree rotated state by means of the retaining force.

During this course of action, the third latching protrusion 402 of the rotating unit 400 pushes the first latching protrusion of the retaining ring 430 to thereby rotate together. The second latching protrusion 434 of the retaining ring 430 is latched with the rotation-limiting protrusion 426, and thus the rotating unit 400 cannot be further rotated in the same direction beyond the 180-degree rotated state.

In this way, if the second body 310 rotates 180-degree, again the liquid crystal window 312 takes a portrait form again. The control unit detects the rotation of the rotating unit 400 through the sensor and controls the image output to the liquid crystal window 312 so as to be displayed in a portrait fashion. The user can use inherent functions of the communication terminal.

On the other hand, the procedures of closing the first body 300 with the second body 310 from the opened state can be carried out in the reverse order of the above.

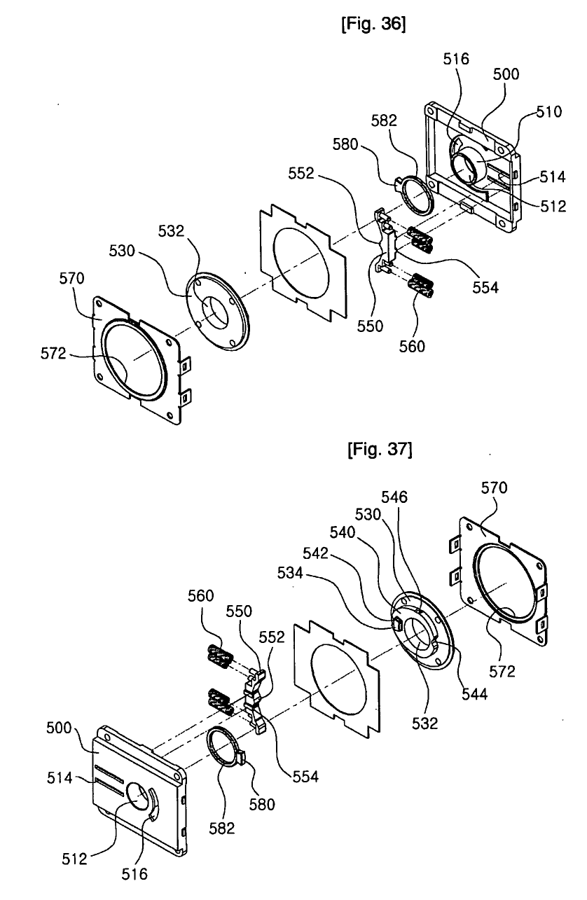

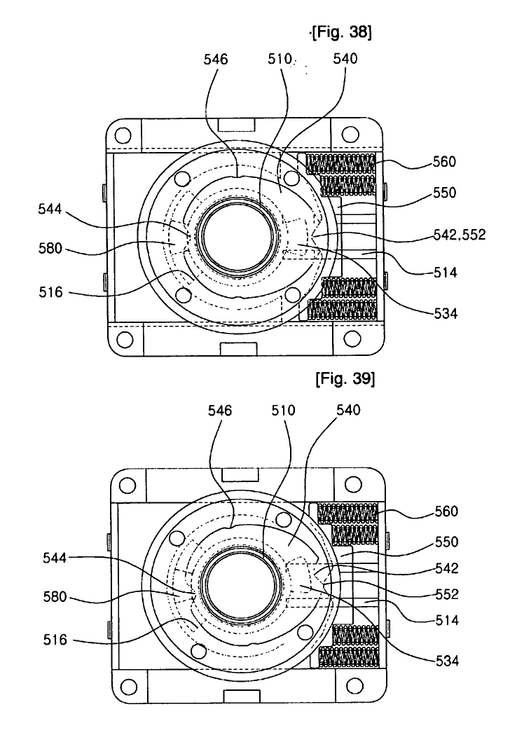

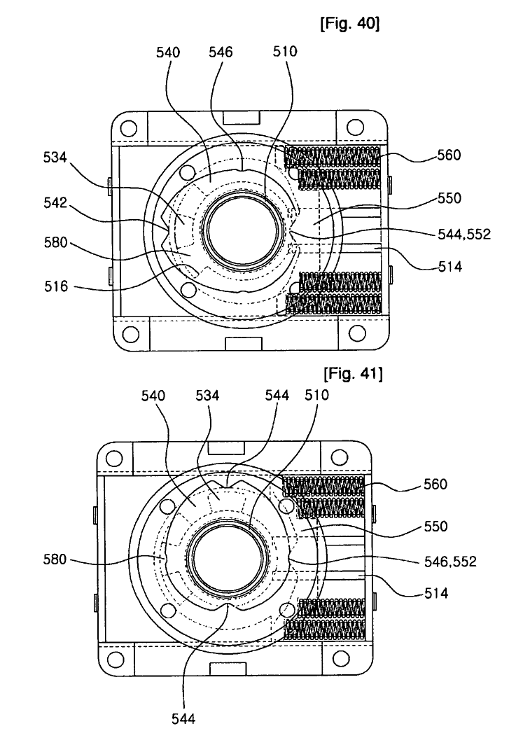

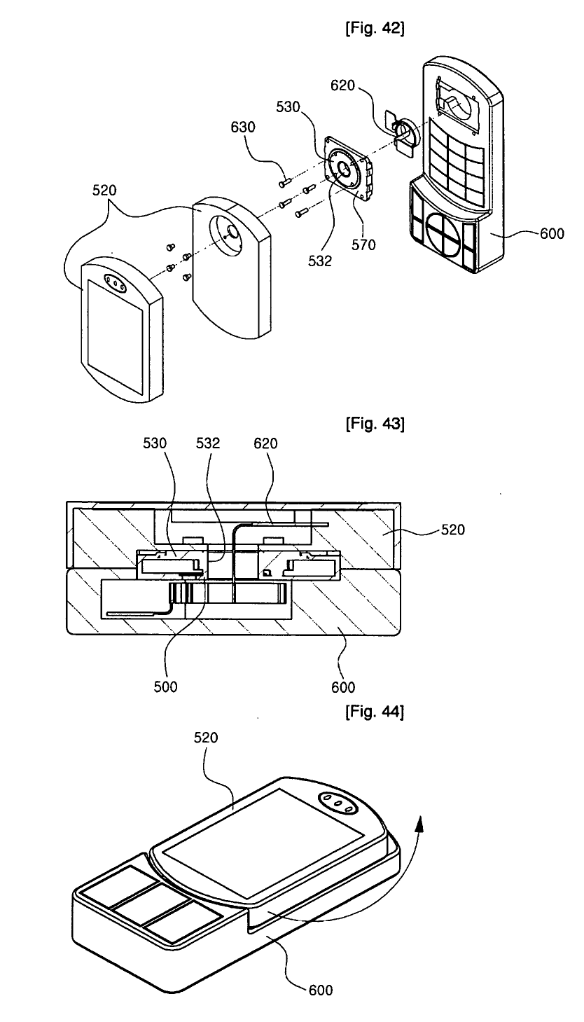

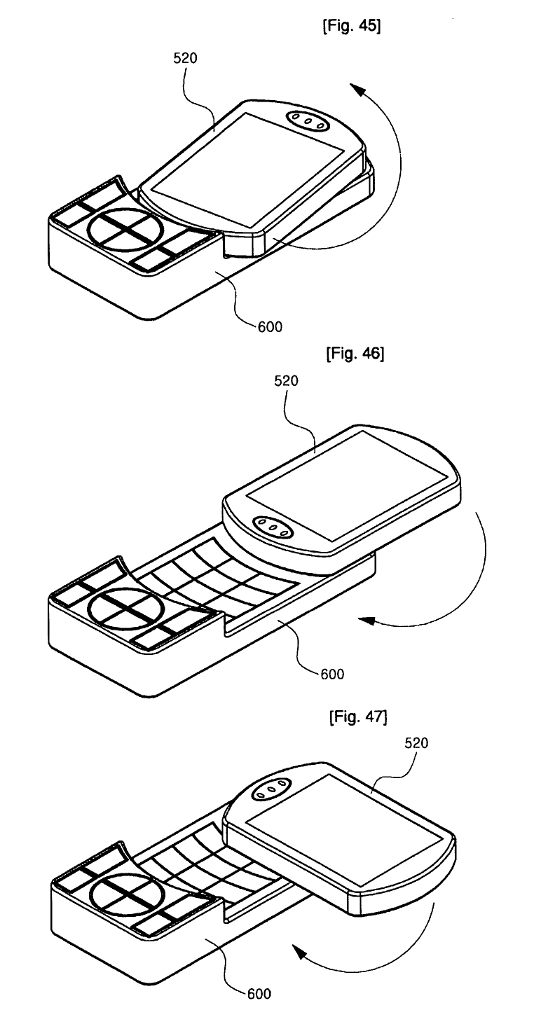

Hereafter, another embodiment of the invention will be described, referring to FIGS. 36 to 47.

As illustrated in FIGS. 36 to 47, this embodiment includes a fixing unit 500 and a rotating unit 530 rotatably connected to the fixing unit 500.

Furthermore, in the swing-type tilting mechanism of this embodiment, an oval cam 540 is fixed in an eccentric position from the rotational center of the rotating unit 530. A mobile block 550 is installed in the fixing unit 500 in such a way as to move towards and away from the rotational center of the cam 540. In addition, a resilient member is provided to exert a resilient force onto the mobile block 550.

Formed in one of the fixing unit 500 and the rotating unit 530 is a rotation hole 532, and formed in the other one thereof is a rotation shaft 510, which is rotatably combined with the rotation hole 532.

The rotating unit 530 rotates around the rotation shaft 510 in both directions.

Since the cam 540 has an oval form, the pushing force of the mobile block 550 is converted into a force for rotating the rotating unit 530 via the cam 540.

In addition, the cam 540 is fixed in a position eccentric from the rotational center of the rotating unit 530. Thus, if the mobile block 550 pushes the outermost portion protruding from the rotational center of the cam 540, the cam 540 and the rotating unit 530 rotate 180-degree.

Formed in the central area of the rotation shaft 510 is a central hole 512, through which a signal line 620 leading to the rotating unit 530 from the fixing unit 500 passes.

The swing-type display tilting mechanism is provided with a clutch means for holding the rotating unit 530 in place at the initial state and at a certain degree-rotated state.

The clutch means is formed of a protrusion 552 formed in the mobile block 550. A first depressed portion 543 to be engaged with the protrusion 552 is formed in the outermost portion protruding from the rotational center of the cam 540.

In addition, a second depressed portion 544 to be engaged with the protrusion 552 is formed in a place, which is in symmetry with the first depressed portion 542 about the rotational center.

Therefore, the rotating unit 530 remains in place at the un-rotated state by engagement of the protrusion 552 with the first depressed portion 542, and remains in place at the 180-degree rotated state in both direction by engagement of the protrusion 552 with the second depressed portion 544.

If the protrusion 552 is released from the first depressed portion 542, the mobile block 550 pushes the cam 540 to rotate the rotating unit 530. Thus, the cam 540 and the rotating unit 530 can be automatically rotated 180-degree in both directions.

Formed between the first depressed portion 542 and the second depressed portion 544 in the mobile block 550 is a third depressed portion 546 to be engaged with the protrusion 552.

Thus, when a user rotates the rotating unit 530 by 90-degree in either direction, the rotating unit 530 remains in the rotated state by means of engagement of the protrusion 552 with the third depressed portion 546.

The depth of the third depressed portion 546 is made to be shallower relative to the first depressed portion 542 and the second depressed portion 544.

The mobile block 550 is provided with a guide rail 554 formed in the moving direction of the mobile block 550. The fixing unit 500 is provided with a guide groove 514 where the guide rail 554 is slidably connected. Thus, the mobile block 550 can performs a stable linear motion along the guide groove 514.

On the other hand, the resilient member is formed of at least one compression spring 560, which is supported by the fixing unit 500 and pushes the mobile block 550 towards the cam 540.

The above swing-type display tilting mechanism is provided with a cover 570, which is connected to the fixing unit 500 from the outside of the rotating unit 530, thus preventing the rotating unit 530 from being released from the fixing unit 500. The cover 570 has an opening hole 572 formed so as to expose part of the rotating unit 530.

In addition, the swing-type display tilting mechanism is provided with a retaining unit for holding the rotating unit 530 in place at a certain degree-rotated state relative to the fixing unit 500.

The retaining unit is composed of a latching protrusion 534 fixed to either one of the fixing unit 500 and the rotating unit 530, and a latching plate 580 formed in the other one of the fixing unit 500 and the rotating unit 530 so as to move in the rotating direction of the latching protrusion 534, which thereby can be retained at the 180-degree rotated state in either direction.

In addition, either one of the fixing unit 500 and the rotating unit 530 is provided with an arcuate groove 516 formed such that the latching protrusion 580 can be movably inserted thereinto.

The arcuate groove 516 has a size to limit the movement of the latching plate 580 such that the latching protrusion 534 is retained in place by the latching plate 580 at the 180-degree rotated state in either direction.

In addition, a ring 582 is fixed to the latching plate 580. The ring 582 is rotatably connected to the central shaft of the rotating unit 530. Thus, the latching plate 580 can perform a stable swing motion around the ring 582.

When the display tilting mechanism of this embodiment is mounted on a portable communication terminal, the fixing unit 500 is fixed to a main body 600 using a screw 630 and the rotating unit 530 is fixed to the display 520 using a screw 630. At this state, the rotating unit 530 is exposed through the opening hole 572 of the cover 570.

The display 520 can be rotated, together with the rotating unit 530, around its rotation shaft 510 relative to the main body 600. A signal line 620 leads from the main body via the center hole 512 of the rotation shaft 510 to the display 520.

Furthermore, the protrusion 552 of the mobile block 550 is engaged with the first depressed portion 542 of the cam 540 such that the rotating unit 530 and the display 520 can be retained at the closed state with a desired retaining force by means of the resilience of the compression spring 560.

The operation of the above-described mechanism will be explained. When the display 520 is tilted in a swing motion, the rotating unit 530 rotates together with the display 520. Thus, the protrusion 552 of the mobile block 550 is released from the first depressed portion 542, and thereafter pushes the cam 540 in the rotating direction.

Since the cam 540 is placed eccentrically from the rotational center of the rotating unit 530, the pushing force of the protrusion is converted into a rotating force. Accordingly, the rotating force is exerted on the rotation shaft 510 and the display 520, so that the display 520 is automatically rotated into a 180-degree open state.

When the display 520 is rotated 180-degree, the latching protrusion 534 of the rotating unit 530 contacts the latching plate 580 to push the latching plate 580 towards the edge area inside the arcuate groove 516.

Thus, by means of the latching plate 580, the latching protrusion 534 is prevented from further rotating. The rotating unit 530 and the display 520 stop.

At this time, the second depressed portion 544 of the cam 540 is engaged with the protrusion of the mobile block 550, so that the rotating unit 530 and the display 520 remain in place.

In this way, if the portable communication terminal is opened, the user can use inherent functions of the terminal such as voice communication and word transfer.

On the other hand, in the case where the display 520 is opened 90-degree to watch a movie or the like, the display 520 is rotated 90-degree in the opposite direction from the 180-degree open state.

When the display 520 is rotated 90-degree, the third depressed portion 546 of the cam 540 is engaged with the protrusion 552 to thereby produce a desired retaining force.

Therefore, the rotating unit 530 and the display 520 remain in the 90-degree rotated state. At this state, a user can watch a movie through the display 520.

In addition, in order to close the display 520, the display 520 continues to rotate in the opposite direction to when it is opened.

When the display 520 is closed, the first depressed portion 542 of the cam 540 is engaged with the protrusion 552 to generate a desired retaining force, thus stabilizing the rotating unit 530 and the display 520.

In this embodiment, the display 520 is explained and illustrated as being rotated counterclockwise, but the clockwise operation can be performed in the same manner.

### INDUSTRIAL APPLICABILITY

As described above, the display can be rotated into a landscape form at the state where it is turned about a hinge relative to the main body.

Thus, when watching a movie or the like, the image can be display in a normal orientation.

In addition, with a folder-type terminal, the display can be rotated into a landscape form such that an image can be displayed in a landscape mode when watching a movie or the like.

Although the present invention has been described with reference to several preferred embodiments, the description is illustrative of the invention and not to be construed as limiting the invention. Various modifications and variations may occur to those skilled in the art, without departing from the scope and spirit of the invention as defined by the appended claims.

1. A display tilting mechanism for a communication terminal, in which a display is rotatably connected to a supporter hingedly pivoting on a main body of the communication terminal, the mechanism comprising:
(a) a fixing unit fixedly installed in the supporter;
(b) a rotating unit connected with the display and rotatably installed relative to the fixing unit;
(c) a supporting unit connected with the fixing unit in such a way that the rotating unit is not released when it rotates on the fixing unit; and
(d) a retaining unit for holding the rotating unit in place at the initial state and rotated state thereof when rotated on the fixing unit.

2. The display tilting mechanism according to claim 1, wherein a guide shaft is formed in the center of the fixing unit and a guide hole is formed in the center of the rotating unit, the guide shaft being rotatably inserted in to the guide hole.

3. The display tilting mechanism according to claim 1, wherein the retaining unit includes:
(i) a cam provided on the rotating unit, the cam forming a cam-line configuration of a rectangular cross-section relative to the rotational center thereof, a latching groove being formed in both ends of a long axial portion and a short axial portion of the cam;
(ii) slider blocks installed in parallel above and below the fixing unit so as to enable to inwardly and outwardly slide, a spring being installed between corresponding ends of the slider blocks; and
(iii) a latching portion provided in a central face of each slider block so as to be selectively latched with the latching groove of the cam.

4. The display tilting mechanism according to claim 3, wherein the slider block is provided with a guider formed at both lateral faces thereof such that the slide block can be slidably moved inwardly and outwardly, and the fixing unit is provided with a guide rail at a corresponding inner lateral face thereof so as to support both lateral faces of the guider.

5. The display tilting mechanism according to claim 3, wherein the latching portion includes:
(i) a pair of brackets protruded in parallel from the central face of the slider block, a through-hole being formed in the brackets; and
(ii) a retaining roller rotatably connected to the brackets using a shaft such that the retaining roller is resiliently latched with the latching groove while rolling along the outer face of the cam.

6. The display tilting mechanism according to claim 3, wherein each of the slider blocks is provided at its both end portions with a hanger groove having a hook-like shape, to which both ends of the spring can be hung.

7. The display tilting mechanism according to claim 1, wherein the fixing unit is provided at its inner face with a guide rib having a desired radius of curvature for rotatably guiding the outer circumferential surface of the rotating unit when it rotates.

8. The display tilting mechanism according to claim 2, wherein the guide shaft is provided with a through-hole formed at the central area thereof, a signal line leading from the supporter to the display passing through the through-hole.

9. The display tilting mechanism according to claim 2, wherein the rotating unit is provided with a connector to be connected with a display and the supporting unit is provided with a through-hole formed therein such that the connector can pass through the through-hole.

10. The display tilting mechanism according to claim 1, wherein the retaining unit includes:
(i) a cam provided in the central face of the rotating unit, the cam having a protrusion formed so as to contact the fixing unit and thus restrict the rotating angle of the rotating unit;
(ii) a slider block pushing the protrusion formed in the cam such that a desired retaining force can be generated at the initial and rotated states of the rotating unit; and
(iii) a spring providing a resilience force to the slider block.

11. The display tilting mechanism according to claim 10, wherein the fixing unit is provided with a contact portion formed so as to restrict the rotation of the rotating unit to within 90 degrees.

12. The display tilting mechanism according to claim 10, wherein a guide rib is formed in the slider block and the fixing unit is provided with a guide groove formed so as to guide movement of the guide rib.

13. A display tilting mechanism for a communication terminal, in which a display is rotatably connected to a supporter hingedly pivoting on a main body of the communication terminal, the mechanism comprising:
(a) a fixing unit fixed to the supporter;
(b) a rotating unit rotatably coupled to the fixing unit and simultaneously connected to the display, the rotating unit having at least one depressed portion formed at a position corresponding to a restriction angle against the rotation of the display;
(c) a retaining unit having a protrusion engaged with the depressed portion to exert a retaining force on the rotating unit, the retaining unit being prevented from being rotated, by means of the fixing unit; and
(d) a resilient member generating a resilient force for pressing the retaining unit towards the rotating unit.

14. The display tilting mechanism according to claim 13, wherein a rotation shaft is formed in the central area of the fixing unit, the rotating unit is provided with a rotation hole formed in the central area thereof such that the rotation shaft can be rotatably inserted into the rotation hole, and a connection member is connected to that portion in the rotation shaft that passes through the rotation hole, thereby preventing release of the rotation shaft.

15. The display tilting mechanism according to claim 14, wherein the rotation shaft is provided with a through-hole formed in the central area thereof such that a signal line leading to the display from the supporter passes through the through-hole.

16. The display tilting mechanism according to claim 13, wherein the depressed portion is formed at a position corresponding to a portrait position and a landscape position respectively of the display.

17. The display tilting mechanism according to claim 13, wherein a latching protrusion is formed in the retaining unit, and the fixing unit is provided with a depressed groove formed so as to be engaged with the latching protrusion.

18. The display tilting mechanism according to claim 13, wherein the resilient member is formed of a donut-shaped leaf spring, which is composed of a valley portion contacting with the fixing unit and a ridge portion contacting with the retaining unit.

19. The display tilting mechanism according to claim 13, wherein the fling unit is provided with a protrusion formed therein such that the display is rotated within a desired range of angle, and the rotating unit is provided with a latching protrusion formed such that the display can be stopped by means of the protrusion at the initial state and the 90-degree rotated state of the display.

20. A swing-type display tilting mechanism comprising:
(a) a rotating unit fixedly attached to a second body;
(b) a fixing unit fixedly attached to a first body, the fixing unit being connected to the rotating unit such that the second body and the first body are rotated relative to and in contact with each other;
(c) a clutch member for generating a desired retaining force by being engaged with a depressed portion formed in the rotating unit, the depressed portion being formed in at least one angular position intended to exert the retaining force against rotation of the second body, the clutch member being prevented from rotating by means of the fixing unit; and
(d) a resilient member generating a resilient force for pressing the clutch member towards the rotating unit.

21. The swing-type display tilting mechanism according to claim 21, wherein a rotation shaft is formed in the central area of the rotating unit, the fixing unit is provided with a rotation hole formed in the central area thereof such that the rotation shaft-can be rotatably inserted into the rotation hole, and a connection member is connected to that portion in the rotation shaft that passes through the rotation hole, thereby preventing release of the rotation shaft.

22. The swing-type display tilting mechanism according to claim 21, wherein the rotation shaft is provided with a through-hole formed in the central area thereof such that a signal line leading to the second body from the first body passes through the through-hole.

23. The swing-type display tilting mechanism according to claim 20, wherein the fixing unit is provided with an insert hole formed so as to receive the clutch member such that the clutch member can be moved together when the fixing unit rotates and simultaneously the clutch member can be allowed to move towards the resilient member and the rotating unit.

24. The swing-type display tilting mechanism according to claim 20, wherein the clutch member is formed of a ball, and the depressed portion is formed of a semi-spherical groove with which part of the ball is engaged.

25. The swing-type display tilting mechanism according to claim 20, wherein the depressed portion is formed at a position to be engaged with the clutch member at states respectively where the second body closes the first body and the second body is rotated 90-degree or 180-degree relative to the first body.

26. The swing-type display tilting mechanism according to claim 20, wherein the resilient member is formed of a C-shaped spring, inner side of which is contacted with the clutch member to thereby press the clutch member towards the depressed portion.

27. The swing-type display tilting mechanism according to claim 26, wherein the fixing unit is provided with a protrusion protruded towards the resilient member, and the opening of the resilient member is latched with the protrusion to thereby rotate along with the fixing unit.

28. The swing-type display tilting mechanism according to claim 20, further comprising a retaining unit for preventing excessive rotation of the rotating unit in a particular direction.

29. The swing-type display tilting mechanism according to claim 20, further comprising a retaining unit installed such that the rotating unit can be rotated in both directions relative to the fixing unit and cannot be further rotated from a state rotated with certain predetermined degrees.

30. The swing-type display tilting mechanism according to claim 28 or 29, wherein the retaining unit includes:
(i) a retaining ring rotatably installed between the rotating unit and the fixing unit, the retaining ring being provided with a first latching protrusion formed to the rotating unit side and a second latching protrusion formed to the fixing unit side;
(ii) a third latching protrusion formed in the rotating unit and contacting the first latching protrusion to be retained; and
(iii) a rotation-limiting protrusion formed in the fixing unit so as to be placed in both sides respectively of the second latching protrusion and spaced apart from each other by the total length of the first latching protrusion, the second latching protrusion and the third latching protrusion, wherein, when the rotating unit rotates, the rotation-limiting protrusion contacts one of the both end portions of the second latching protrusion along its rotating direction to thereby retain the retaining ring.

31. A swing-type display tilting mechanism for a communication terminal, comprising:
(a) a fixing unit;
(b) a rotating unit rotatably coupled to the fixing unit;
(c) an oval cam fixed to the rotating unit;
(d) a mobile block installed in the fixing unit so as to move towards and away from the rotational center of the cam; and
(e) a resilient member for exerting a resilient force on the mobile block.

32. The swing-type display tilting mechanism according to claim 31, wherein either one of the fixing unit and the rotating unit is provided with a rotation hole formed therein, and a rotation shaft is fixed to the other one thereof so as to be rotatably coupled to the rotation hole.

33. The swing-type display tilting mechanism according to claim 32, wherein the rotation shaft has a center hole formed in the center thereof.

34. The swing-type display tilting mechanism according to claim 31, wherein the rotating unit is configured to rotate in either direction relative to the fixing unit.

35. The swing-type display tilting mechanism according to claim 31, wherein the cam is fixed in a position eccentric from the rotational center of the rotating unit.

36. The swing-type display tilting mechanism according to claim 31, further comprising a clutch means for holding the rotating unit in place at un-rotated state and at a certain degree-rotated state thereof.

37. The swing-type display tilting mechanism according to claim 31, wherein the clutch means is formed of a protrusion formed in the mobile block, a first depressed portion to be engaged with the protrusion is formed in the outermost portion protruding from the rotational center of the cam, and a second depressed portion to be engaged with the protrusion is formed in a symmetrical place with the first depressed portion about the rotational center.

38. The swing-type display tilting mechanism according to claim 37, wherein a third depressed portion to be engaged with the protrusion is formed between the first depressed portion and the second depressed portion.

39. The swing-type display tilting mechanism according to claim 37, wherein, when the protrusion is released from the first depressed portion, the mobile block pushes the cam to rotate the rotating unit.

40. The swing-type display tilting mechanism according to claim 31, wherein the mobile block is provided with a guide rail formed in the moving direction of the mobile block, and the fixing unit is provided with a guide groove with which the guide rail is slidably connected.

41. The swing-type display tilting mechanism according to claim 31, wherein the resilient member is formed of at least one compression spring which is supported by the fixing unit and pushes the mobile block towards the cam.

42. The swing-type display tilting mechanism according to claim 31, further comprising a cover connected to the fixing unit from the outside of the rotating unit, thereby preventing the rotating unit from being released from the fixing unit, and the cover is provided with an opening hole formed so as to expose part of the rotating unit.

43. The swing-type display tilting mechanism according to claim 31, further comprising a retaining unit for holding the rotating unit in plate at a certain degree-rotated state relative to the fixing unit.

44. The swing-type display tilting mechanism according to claim 43, wherein the retaining unit includes a latching protrusion fixed to either one of the fixing unit and the rotating unit, and a latching plate fixed to the other one thereof for retaining the protrusion.

45. The swing-type display tilting mechanism according to claim 44, wherein the retaining unit includes a latching protrusion fixed to either one of the fixing unit and the rotating unit, and a latching plate formed in the other one thereof so as to move in the rotation direction of the latching protrusion such that the latching protrusion can be retained at the 180-degree rotated state in either direction.

46. The swing-type display tilting mechanism according to claim 44, wherein either one of the fixing unit and the rotating unit is provided with an arcuate groove formed such that the latching protrusion can be movably inserted thereinto, wherein the arcuate groove has a size to limit the movement of the latching plate such that the latching protrusion is retained in plate by the latching plate at a state 80-degree rotated in either direction.

47. The swing-type display tilting mechanism according to claim 46, wherein the latching plate is fixed to a ring, which is rotatably connected to the central shaft of the rotating unit.
